(19) United States
(12) Patent Application Publication
(10) Pub. No.: US 2014/0331490 A1
(43) Pub. Date: Nov. 13, 2014

(54) DEVICE FOR A SECURITY SYSTEM

(71) Applicant: GALLAGHER GROUP LIMITED, Hamilton (NZ)

(72) Inventors: Craig David Malins, Hamilton East (NZ); Karen Ruth Tyrrell, Hamilton (NZ)

(73) Assignee: Gallagher Group Limited, Hamilton (NZ)

(21) Appl. No.: 14/361,585

(22) PCT Filed: Nov. 26, 2012
(86) PCT No.: PCT/NZ2012/000217

§ 371 Date: May 29, 2014

(30) Foreign Application Priority Data
Nov. 30, 2011 (NZ) 596786

(51) Int. Cl. E04H 17/26; A01K 3/00; E04H 17/04; E04H 17/06; H05K 13/00; H02G 3/02

(52) U.S. Cl. CPC E04H 17/266; H05K 13/0023; H02G 3/02; E04H 17/04; E04H 17/06; A01K 3/005
USPC 29/825; 174/74 R

(57) ABSTRACT

A conductive link and method of use are provided in conjunction with constructing a security system. The link includes a substantially flat elongate body aligned substantially within a first plane. At least one tab extends from each end of the body, each tab having an attachment portion configured to connect an end of the conductive link directly or indirectly to an electric fence strainer. The tabs and attachment portions are positioned substantially within a second plane oriented to be substantially nonparallel to the first plane.

### TECHNICAL FIELD

The present invention relates to a device for a security system and its method of use. In particular, the present invention relates to a conductive link for use in providing a conductive path between electric fence strainers.

### STATEMENT OF CORRESPONDING APPLICATIONS

This application is based on the specification filed in relation to New Zealand Patent Application Number 596786 dated 30 Nov. 2011 the entire contents of which are incorporated herein by reference.

### BACKGROUND ART

This invention will be discussed in relation to improvements in accessories used with wire in an electric security fence. However, a skilled person will appreciate that the principles of the present invention can be applied to tensioning lengths of other materials in different situations and is not necessarily limited to security electric fences and/or wire.

Strainers have been in use for numerous years to aid the tensioning of wire in electrified fences, such as those used in the farming or security industries.

Most current fence strainers utilise a ratchet pivotally attached to a strainer. The ratchet typically has a set of teeth around the circumference of the ratchet that interacts with a locking mechanism such as a pawl which is also attached to the main body of the strainer. The interaction between the teeth and the pawl allows the ratchet to be turned in one direction when tightening the wire, but not in the other direction. The pawl is usually engaged with the teeth of the ratchet due to gravity (or a spring) and held in place by the tension of the fencing wire once strained up and under tension.

Most security fences rely on a system where multiple wires are tensioned in parallel using strainers currently available in the art. Typically, the electrical current is passed from one wire to another wire using two clamps or crimps and a wire link (herein termed a conductive link). The conductive link is usually positioned near to the ratchet along the length of the adjacent wires. This results in an electric current passing through the adjacent fence wires to discourage people/animals from contacting the fence in fear of being shocked or electrocuted. Also, if a wire is cut or shorted out to an adjacent wire then monitoring electronics circuits can send a signal to a control system or sound an alarm indicating a security breach.

However, these systems above have a number of disadvantages as discussed below.

Installation of the conductive links and strainers requires considerable time, skill and effort to provide the desired outcome. This dramatically affects the overall cost (due to labour) in fence preparation, maintenance and replacement.

Furthermore, as the conductive link and strainer are separate units, the system described above can be untidy and unappealing to the onlooker. This can be an issue for property holders that require security fences, yet want to maintain an aesthetic appearance to their fence and property.

Wires in fences are prone to loosening over time (due to stretching), and the strainers are often periodically used to re-tension the wires; usually rotation of the ratchet will achieve this result.

However, the conductive links located between the wires can become uneven due to wire adjustment which can add to the untidiness of the fence. Fixing this unappealing feature requires further time, and ultimately cost.

Furthermore, as the conductive links are typically inflexible, the conductive links only have a certain amount of movement which will ultimately hinder the amount of possible adjustment of the wires. Again, re-adjustment of the conductive links to address this problem can take further time and effort.

Such systems can also present a risk that a perpetrator can cut the security wire upstream of the conductive link's position to avoid triggering an alarm.

In the PCT patent application published as WO2011040826, a solution to this problem is discussed whereby a conductive component provides a conductive path from the point of connection of the wire to the strainer, through the housing of the strainer to provide an attachment point. A conductive link may then be fastened to the attachment point at one end, and to another strainer, or electric fence energiser at the other. As the conductive link is not directly fastened to the wire itself, the fence may be tensioned without adjustment of the interconnection of the wires.

While an improvement over previously known solutions, there remains room for improvement.

In particular, it would be beneficial to:
ensure sufficient physical separation of the conductive link from the fence installation to prevent arcing in high voltage situations; and/or
make the electrical path formed by the links more difficult to follow visually; and/or
configure the links such that a potential intruder is discouraged from scaling the fence using the links.

It is an object of the present invention to address the foregoing problems or at least to provide the public with a useful choice.

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein, this reference does not constitute an admission that any of these documents form part of the common general knowledge in the art, in New Zealand or in any other country.

Throughout this specification, the word “comprise”, or variations thereof such as “comprises” or “comprising”, will be understood to imply the inclusion of a stated element, integer or step, or group of elements integers or steps, but not the exclusion of any other element, integer or step, or group of elements, integers or steps.

Further aspects and advantages of the present invention will become apparent from the ensuing description which is given by way of example only.

### DISCLOSURE OF THE INVENTION

According to one aspect of the present invention there is provided a conductive link, including:
a substantially flat elongate body aligned substantially within a first plane;
at least one tab extending from each end of the body, each tab having an attachment portion configured to connect an end of the conductive link directly or indirectly to an electric fence strainer,
   the conductive link characterised in that
the tabs and attachment portions are positioned substantially within a second plane oriented to be substantially non parallel to the first plane.

According to another aspect of the present invention there is provided a method of constructing a security system using at least one conductive link having an elongate body, the method including the steps of:
a) attaching a first electric fence strainer to a support post;
b) attaching a second electric fence strainer to the support post in a spaced relationship to the first strainer;
c) attaching a conductive link to the first and second strainers, wherein the conductive link is positioned to provide a conductive path between the strainers;
   the method characterised by the step of
d) ensuring that the body of the conductive link is positioned relative to the strainers such that it is substantially non parallel to the surfaces where the conductive link is attached.

In a preferred embodiment, the angle between the first plane and second plane is between 45 degrees and 90 degrees.

Preferably the angle between the first plane and second plane is substantially 45 degrees.

The inventors have identified this angle as enabling effective installation of a security system by providing:
1) Physical separation of the conductive link from the support post to which the strainers are attached, and/or between conductive links of alternating strainers and other wires. This may minimise the likelihood of arcing between the conductive components in high voltage applications and reduce the fire risk associated with such arcing, of short circuits being formed by debris, and the potential for false alarms; and
2) Clearance with regard to support posts and other components of the fence installation. This is important for meeting standards requirements, as well as providing a difficult to climb structure which minimises arcing.

Further, within security installations, it is desirable that the ability of potential intruders to follow the conductive path between wires be minimised. This reduces the likelihood that the intruder can determine a way of scaling or breaching the fence by identifying non-electrified wires. By ensuring that the body of the conductive link is at an angle to the tab (and thus the strainer to which it is connected) the conductive link becomes more difficult to see from a distance from particular angles. It is envisaged that this effect may be amplified by arranging the connection of the conductive link to a strainer such that substantial portions of the link and connection points are obscured by the strainer's profile.

Additionally, this angle means that the conductive link protrudes from the fence in such a way that an intruder attempting to scale the fence using the links may be forced to grip the thin edges of the body. This makes the fence difficult to climb via the conductive links. It is envisaged that the edges of the link may be de-burred to prevent injury by innocent touching—while still deterring gripping of the link to bear the weight of an intruder.

Preferably the body is arcuate in shape. This may be in a continuous curve, or by use of bent sections. At the very least it is envisaged that the body will be shaped to form a bridge between the tabs.

In doing so clearance is provided, particularly where the link spans a space between strainers which may contain other fence componentry, such as other strainers or links. Alternating links may be orientated in different directions in order to maximise this clearance.

An arcuate shape also assists in making the fence difficult to climb using the links, with the minimal clearance making it difficult to insert hands or feet into the gap, and the shape preventing even distribution of weight across the handhold or purchase to the foothold.

Further, it is envisaged that this shape may minimise material costs, both in terms of the volume of material used and also maximising the number of links which may be obtained from a sheet of material.

Minimising the length and maximising the cross-sectional area of the conductive links may also reduce power loss due to lower resistance of the link. This may have flow on effects in terms of efficiency and cost savings.

The single angle between body and the tabs, along with the curved shape may also serve to enhance the aesthetic appeal of a security fence installation. While functionality is assumed as the primary concern in a setting where electrified fencing is required, in many cases the installation is exposed to view, either by the public, employees, or other visitors to the site. As with most infrastructure, it is generally desirable to maintain the aesthetics of even functional devices or systems.

Preferably, the conductive link of the present invention is made of galvanized steel, particularly zinc, or zinc aluminium.

In a preferred embodiment the link is made of high tensile material configured to retain its original shape after deflection. This may prevent or at least minimise the potential for shorting of the link after deflection.

In a more preferred embodiment the conductive link has a G550 tensile strength and

Z450 level of galvanising.

It should be appreciated that this is not intended to be limiting, and that the conductive link may be made of any suitable material, or combination of materials known to a person skilled in the art for conducting electricity.

The conductive link may be made of sheet metal. This enables the ready and economical manufacture of the links via stamping of the sheet metal blanks, and provides thin edges which are previously discussed as providing a further deterrent to potential intruders due to the difficulty in using same for climbing.

In preferred embodiments the elongate body includes at least one strengthening ridge. It should be appreciated that the inclusion of at least one strengthening ridge is not intended to be limiting. Further, it may be determined that the ridge is not required in links spanning a short distance.

The strengthening ridge may be punched or pressed into the body at the time of manufacture, particularly where the link is made of sheet material.

Preferably the attachment portion includes an aperture. It is envisaged that the aperture will receive a conductive projection from the strainer, locating the link in position as it is fastened in place. In particular, the projection may be threaded and configured to interact with a nut to then fasten the link to the strainer. It should be appreciated that this is not intended to be limiting, and that the link may be connected to a strainer by any suitable means known to a person skilled in the art.

The aperture may include a raised annulus, increasing the electrical contact between the link and the strainer or other conductive element used in fastening of the link. It is envisaged that this raised annulus may be formed by pressing or punching the shape into each tab of the link.

Some of the advantages of the current invention over the prior art include:
higher reliability by reducing the likelihood of arcing or short-circuiting occurring;
greater efficacy through presentation of reduced visual profile and obscuring of connection or termination points, making identification of electrical path more difficult to identify;
improved deterrent effect by presenting difficult to grip edges to intruders attempting to scale the fence using the conductive links, and minimising the footholds available; and
superior aesthetic appeal by reducing visibility of links, and reducing the number of hard angles in the design.

### BRIEF DESCRIPTION OF THE DRAWINGS

Further aspects of the present invention will become apparent from the ensuing description which is given by way of example only and with reference to the accompanying drawings in which:

FIGS. 1a-c illustrate a strainer in conjunction with a conductive link according to one aspect of the present invention;

FIGS. 2a,b illustrate a conductive link according to another embodiment of the present invention;

FIGS. 3a,b illustrate conductive links according to another embodiment of the present invention

FIG. 4 shows the use of the conductive links in an electric fence according to an embodiment of the present invention.

### BEST MODES FOR CARRYING OUT THE INVENTION

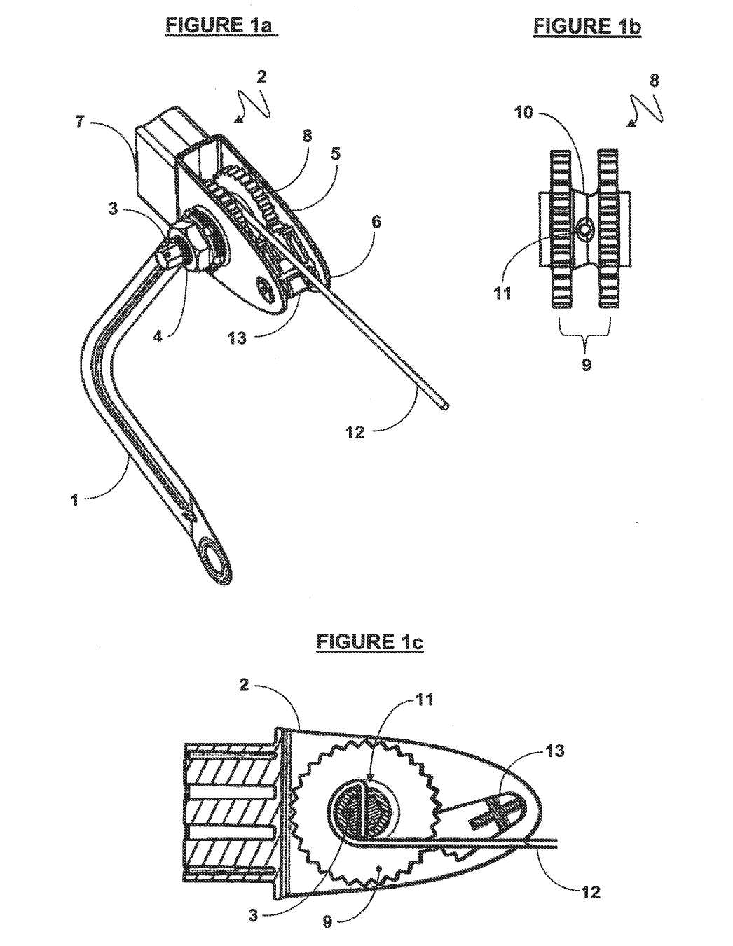

As shown generally in FIG. 1a, a conductive link (1) of the present invention is illustrated in conjunction with a strainer (2).

The strainer (2) is made substantially of a plastics material except for a conductive component (3), and a fastener in the form of a nut (4). The strainer (2) includes a housing with a head portion with rounded sides (5), rounded tips (6) and a box shaped backing portion (7).

The strainer (2) includes a tensioning device in the form of a ratchet (8). The ratchet (8) may be made of either a non-conductive material such as plastic, or a conductive material.

FIG. 1b shows that the ratchet (8) has two “wheels” (9) joined by a central portion (10). The ratchet (8) has an aperture (11) which passes through the central portion (10) of the ratchet (8).

As illustrated by FIG. 1c, a wire (12) is passed through the aperture (11), where it contacts the conductive component (3), which in turn projects from the housing as illustrated in FIG. 1a.

The ratchet wheels (9) each have a set of symmetrically shaped triangular teeth that project outwards from the circumference of the ratchet wheels (9) to engage with a pawl (13). This allows rotation of the ratchet (8) in one direction, but is able to prevent rotation of the ratchet (8) in the opposition direction.

In operation, the wire (12) is tensioned by rotation of the ratchet (8) via the conductive component (3), or a shaped tensioning connection such as a hexagonal aperture (not illustrated) configured to engage with a tool such as an Allen key.

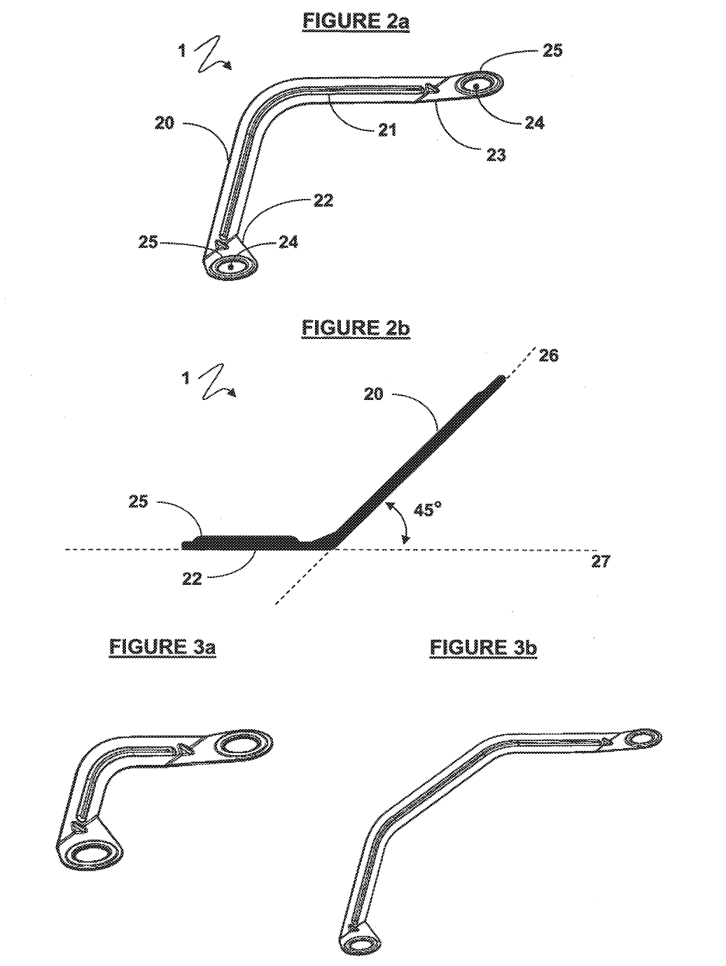

FIG. 2a shows a perspective view of the conductive link (1). The link (1) includes a flat elongate body (20) which is arcuate in shape. A strengthening ridge (21) is pressed into a substantial length of the body (20) to provide rigidity.

A first tab (22) and second tab (23) extend from the respective ends of the body (20). Each tab (22, 23) includes an attachment portion in the form of an aperture (24), which may be used to connect the link (1) to a strainer, as illustrated by FIG. 1a.

Each aperture (24) has a raised annulus (25) which assists in ensuring good electrical contact between the link (1) and conductive component (3) and nut (4) of FIG. 1a.

As illustrated by FIG. 2b, the body (20) is aligned substantially within a first plane (26), while the tabs are positioned substantially within a second plane (27) oriented to be substantially non parallel to the first plane (26)—specifically at an angle of substantially 45 degrees.

FIGS. 3a and 3b illustrate alternative embodiments of the conductive link (1) of FIGS. 1 and 2.

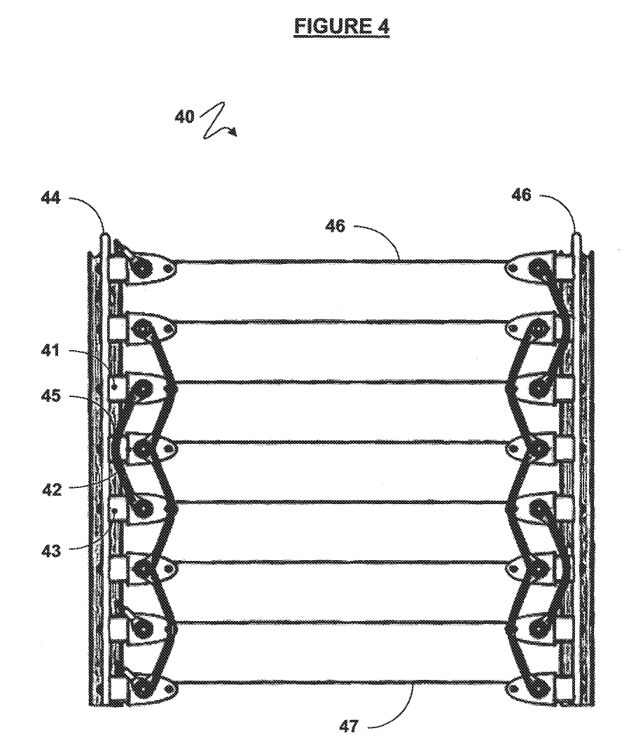

FIG. 4 shows a multitude of strainers, exemplified by strainers (41, 42, and 43), mounted to posts (44) to form a security system (40), as viewed from the inner perimeter.

The configuration of the strainers (2) and conductive links (1) is one example of how the current invention can be used to configure an electric fence as a security system. The metal conductive link (45) links two strainers (41 and 43) positioned downstream or upstream and which are separated by a middle strainer (42).

In the configuration shown in FIG. 3, the live wire (46) is connected at the ends so that it zigzags in as a continuous conductive path. This is so an electric pulse may be sent into the wire at one end and monitored for a cut wire at the other end.

The conductive component is also used as a point of electrical contact for a lead out wire and anti-climb wires (not shown). The connections will be made preferably with a lug crimped on to the feed wire or with the feed wire attached directly to the conductive component via a fastener.

The earth wires, exemplified by earth wire (47), are all connected together so that there are redundant connections. This helps to ensure there will be a shock between any adjacent wire and an earth wire. Other configurations are available, for example two continuous live wires.

Substantially any configuration may be achieved. Typically no more than two metal conductive links are connected to any strainer; however this is not essential.

Preferred configurations are:
Connecting every alternate wire for series circuits e.g. connecting first and third, second and fourth, fifth and seventh, sixth and eighth, etc.
Connecting every alternate wire for parallel circuits e.g. first, third, fifth, seventh, and so on, all connected together
Connecting two adjacent wires e.g. connecting second and third wires.
Connecting two wires that are three wires apart e.g. connecting first and fourth wires.
Connecting wires that are more than three wires apart.

Aspects of the present invention have been described by way of example only and it should be appreciated that modifications and additions may be made thereto without departing from the scope thereof as defined in the appended claims.

What is claimed is:

1. A conductive link, comprising:
a substantially flat elongate body aligned substantially within a first plane;
at least one tab extending from each end of the body;
each tab having an attachment portion configured to connect an end of the conductive link directly or indirectly to an electric fence strainer; and
wherein the tabs and attachment portions are positioned substantially within a second plane oriented to be substantially non parallel to the first

2. A conductive link as claimed in claim 1, wherein the angle between the first plane and second plane is between 45 degrees and 90 degrees.

3. A conductive link as claimed in claim 1, wherein the angle between the first plane and second plane is substantially 45 degrees.

4. A conductive link as claimed in claim 1, wherein the body is arcuate in shape.

5. A conductive link as claimed in claim 1, wherein the elongate body comprises at least one strengthening ridge.

6. A conductive link as claimed in claim 1, wherein the attachment portion comprises an aperture.

7. A conductive link as claimed in claim 6, wherein the aperture comprises a raised annulus.

8. A method of constructing a security system using at least one conductive link having an elongate body, the method comprising the steps of:
attaching a first electric fence strainer to a support post;
attaching a second electric fence strainer to the support post in a spaced relationship to the first strainer;
attaching a conductive link to the first and second strainers, wherein the conductive link is positioned to provide a conductive path between the strainers; and
ensuring that the body of the conductive link is positioned relative to the strainers such that it is substantially non parallel to the surfaces where the conductive link is attached.

9. A method as claimed in claim 8, wherein the body is positioned such that the angle between the body and the strainer is between 45 and 90 degrees.

10. A method as claimed in claim 8, wherein the body is positioned such that the angle between the body and the strainer is substantially 45 degrees.

11. (canceled)

12. (canceled)
